(19) United States
(12) Patent Application Publication
(10) Pub. No.: US 2026/0090044 A1
(43) Pub. Date: Mar. 26, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Chiao-Ti HUANG, New Taipei City (TW); Huiling SHANG, Hsinchu County (TW); Chien-Tai CHAN, Hsinchu City (TW)

(73) Assignee: Taiwan Semiconductor Manufacturing Company, Ltd., Hsinchu (TW)

(21) Appl. No.: 18/896,315

(22) Filed: Sep. 25, 2024

(51) Int. Cl. H01L 29/08; H01L 21/8238; H01L 27/092; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 64/017; H10D 84/0167; H10D 84/017; H10D 84/038; H10D 84/85

(57) ABSTRACT

A method for forming a semiconductor structure is provided. The method includes forming a first active region in which sacrificial layers and channel layers are alternately stacked. A topmost one of the channel layers is a first channel layer. The method further includes forming a first source/drain feature on the first active region, removing the sacrificial layers of the first active region to form first gaps, at least partially removing the first channel layer of the first active region, and forming a first gate stack to fill the first gaps.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with related complementary metal-oxide-semiconductor (CMOS) processes, and their structure allows them to be aggressively scaled-down while maintaining gate control and mitigating SCEs. In related processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIGS. 3A-1, 3B-1, 3C-1, 3D-1, 3E-1, 3F-1, 3G-1, 3H-1, 3I-1, 3J-1, 3K-1 and 3L-1 are cross-sectional views illustrating the formation of a semiconductor structure at various intermediate stages, in accordance with some embodiments of the disclosure.

FIGS. 3A-2, 3B-2, 3C-2, 3D-2, 3E-2, 3F-2, 3G-2, 3H-2, 3I-2, 3J-2, 3K-3 and 3L-2 are cross-sectional views illustrating the formation of a semiconductor structure at various intermediate stages, in accordance with some embodiments of the disclosure.

FIG. 3L-3 is a plan view illustrating the semiconductor structure at an intermediate stage, in accordance with some embodiments of the disclosure.

FIG. 3L-4 is a plan view illustrating the semiconductor structure at an intermediate stage, in accordance with some embodiments of the disclosure.

FIGS. 4A, 4B and 4C-1 are cross-sectional views illustrating the formation of a semiconductor structure at various intermediate stages, in accordance with some embodiments of the disclosure.

FIG. 4C-2 is a plan view illustrating the semiconductor structure at an intermediate stage, in accordance with some embodiments of the disclosure.

FIGS. 5A and 5B-1 are cross-sectional views illustrating the formation of a semiconductor structure at various intermediate stages, in accordance with some embodiments of the disclosure.

FIG. 5B-2 is a plan view illustrating the semiconductor structure at an intermediate stage, in accordance with some embodiments of the disclosure.

FIGS. 6A and 6B are cross-sectional views illustrating the formation of a semiconductor structure at various intermediate stages, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

With the advancement of semiconductor manufacturing processes, the low power consumption is increasingly crucial not only for mobile devices but also for artificial intelligence computing. In order to reduce operating power consumption, low operating voltage (e.g., vdd) and low call capacitance are the two basic solutions. Embodiments of a semiconductor structure and a method for forming the semiconductor structure are provided. The method for forming the semiconductor structure includes a patterning process of channel layers which is performed to globally reduce the number of channel layers in all device regions, or locally reduce the number of channel layers in specific device regions. Therefore, the total cell capacitance of the resulting semiconductor device may be sufficiently reduced, thereby improving the power consumption.

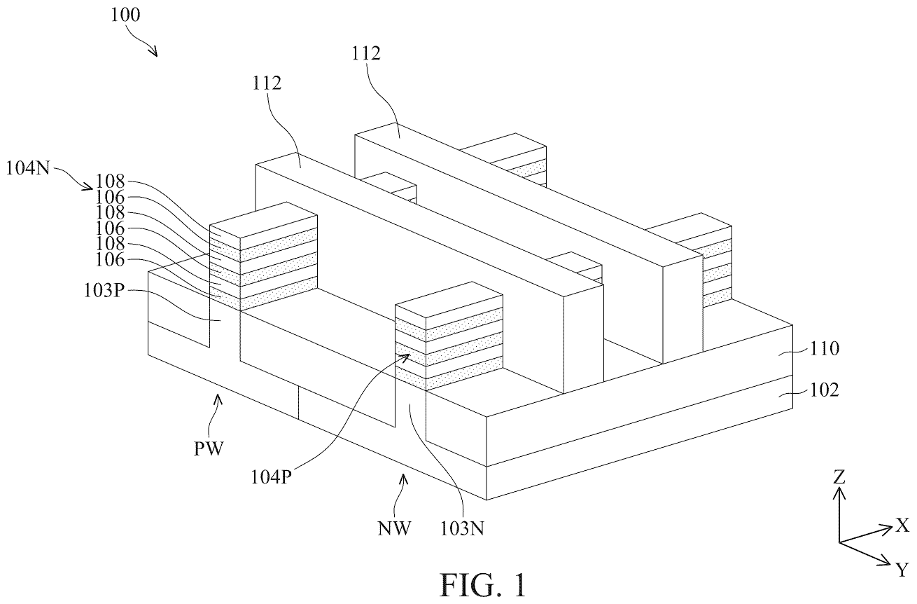

FIG. 1 is a perspective view of a semiconductor structure 100, in accordance with some embodiments. The semiconductor structure 100 includes a substrate 102 and fin structures 104 (including 104N and 104P) over the substrate 102, as shown in FIG. 1, in accordance with some embodiments. The substrate 102 includes a p-type well PW and an n-type well NW immediately adjacent to the p-type well PW, in accordance with some embodiments. The fin structure 104N is formed in the p-type well PW, and the fin structure 104P is formed in the n-type well NW, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104N includes a lower fin element 103P formed from the p-type well PW, and the fin structure 104P includes a lower fin element 103N formed from the n-type well NW, in accordance with some embodiments. The lower fin elements 103P and 103N are surrounded by an isolation structure 110, in accordance with some embodiments. Each of the fin structures 104N and 104P further includes an upper fin element formed from an epitaxial stack including alternating first semiconductor layers 106 and second semiconductor layers 108, in accordance with some embodiments. The second semiconductor layers 108 will form nanostructures (e.g., nanowires or nanosheets) and serve as the channel for the resulting semiconductor devices, in accordance with some embodiments.

The fin structures 104 extend in the X direction, in accordance with some embodiments. That is, the fin structures 104 have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are arranged in an alternating manner, in accordance with some embodiments. It is noted that in the present disclosure, source/drain region(s) or source/drain feature(s) may refer to a source or a drain, individually or collectively dependent upon the context.

Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-routing direction.

Although two fin structures 104 and two gate structures 112 are illustrated in FIG. 1, the semiconductor structure 100 is not intended to be limiting. The number of fin structures and the gate structures may be dependent on the design demand of an integrated circuit and/or performance consideration of resulting semiconductor devices.

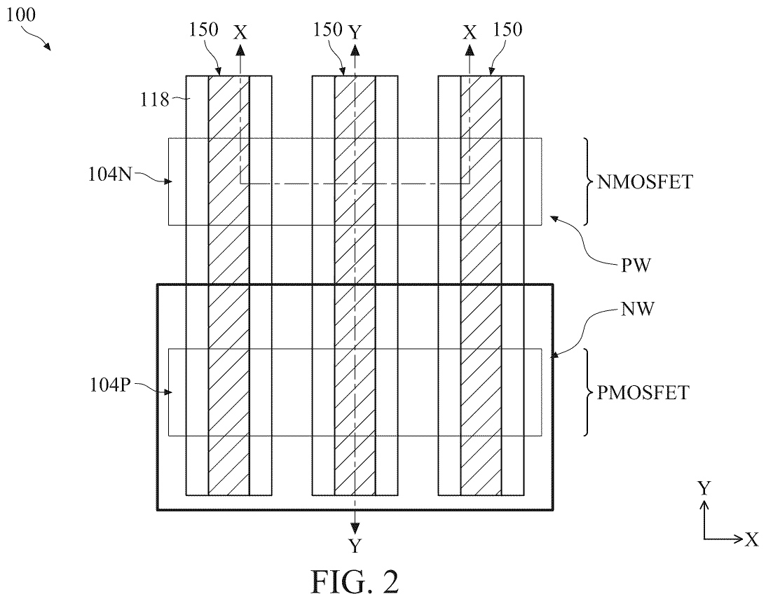

FIG. 2 is a layout of a semiconductor structure 100, in accordance with some embodiments. The semiconductor structure 100 may be or include nanostructure devices (e.g., GAA FETs), in accordance with some embodiments. The semiconductor structure 100 includes active regions 104 (including 104N and 104P) over a substrate (as shown in FIG. 1), and final gate stacks 150 across the active regions 104, in accordance with some embodiments. The substrate includes a p-type well PW and an n-type well NW, in accordance with some embodiments. The p-type well PW and the n-type well NW are immediately arranged in the Y direction, in accordance with some embodiments. The active region 104N is located on the p-type well PW, and the active region 104P is located on the n-type well NW, in accordance with some embodiments.

Each of the active regions 104 includes a lower fin element and nanostructures formed over the lower element, in accordance with some embodiments. The final gate stacks 150 extend in the Y direction across the lower fin elements, in accordance with some embodiments. The final gate stacks 150 wrap around the nanostructures of the active regions 104N and 104P. Gate spacer layers 118 are formed along the opposite sides of the final gate stack 150, in accordance with some embodiments.

The final gate stack 150 is combined with the nanostructures of the active regions 104N and 104P to form nanostructure transistors, in accordance with some embodiments. The nanostructure transistors which are formed over the p-type well PW are n-channel devices (e.g., n-channel nanostructure transistors) NMOSFET, and the nanostructure transistors which are formed over the n-type well NW are p-channel devices (e.g., p-channel nanostructure transistors) PMOSFET.

FIG. 2 further illustrates reference cross-sections that are used in later figures. Cross-section X-X is in a plane parallel to the longitudinal axis (X direction) of the active region 104N and through the active region 104N, in accordance with some embodiments. Cross-section Y-Y is in a plane parallel to the longitudinal axis (Y direction) of the final gate stack 150 and through the final gate stack 150 (or a dummy gate structure), in accordance with some embodiments.

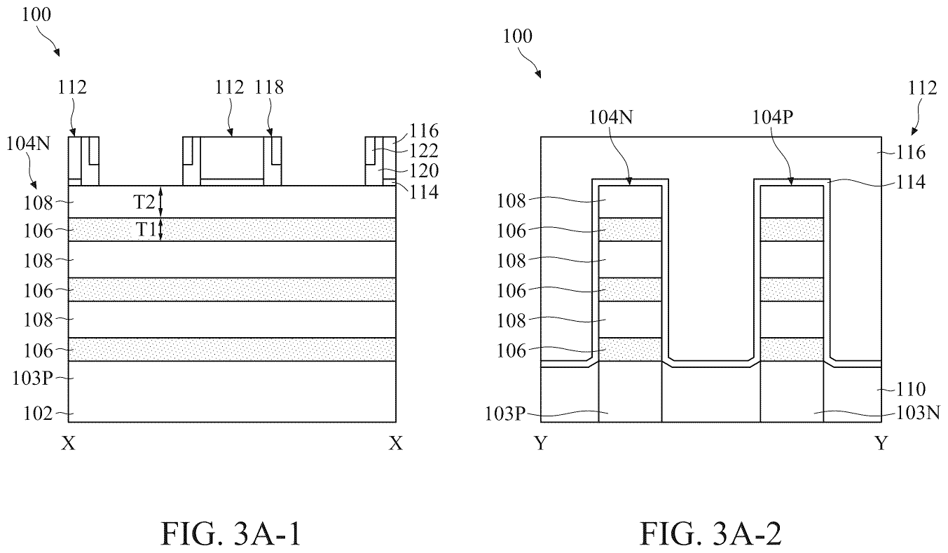

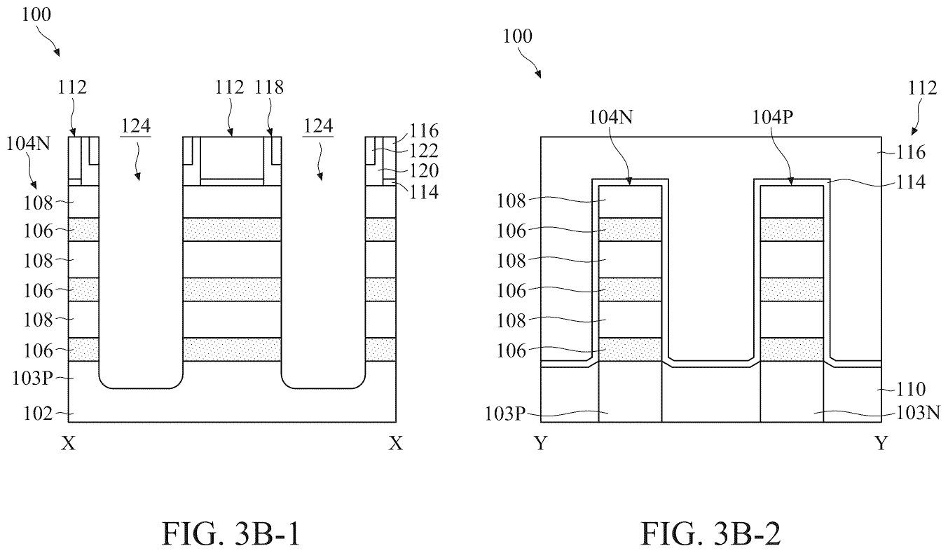

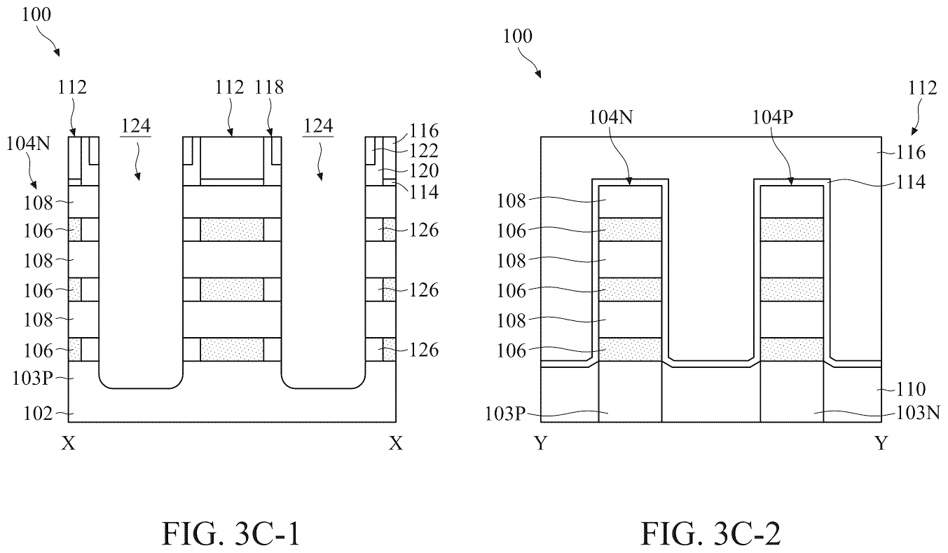

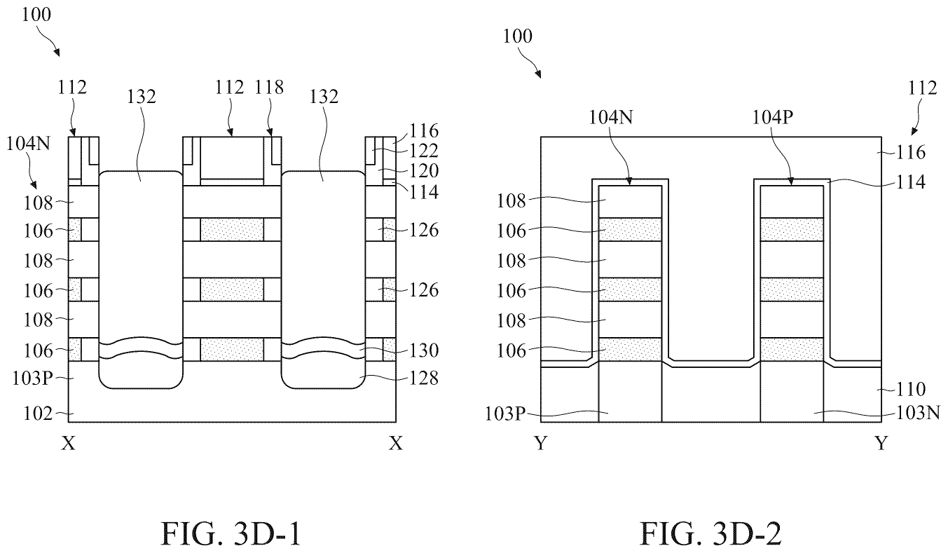

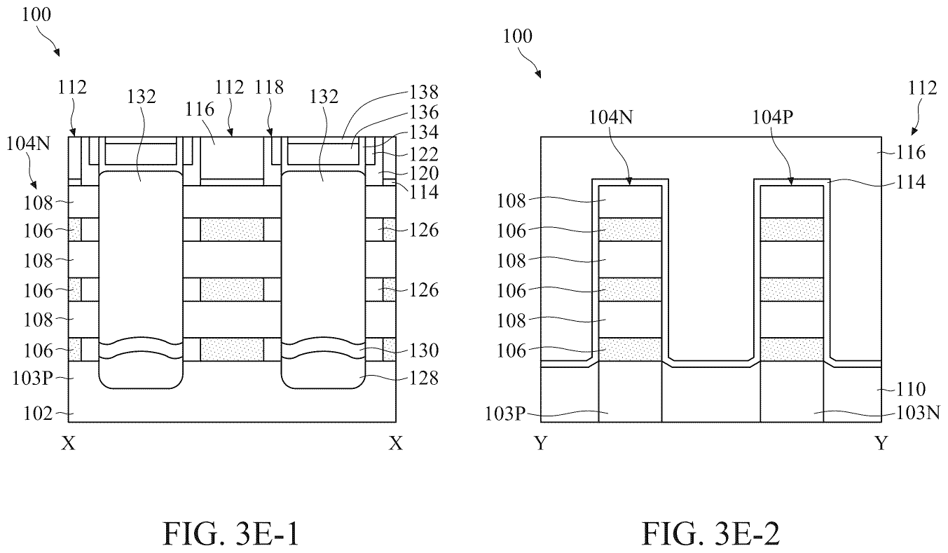

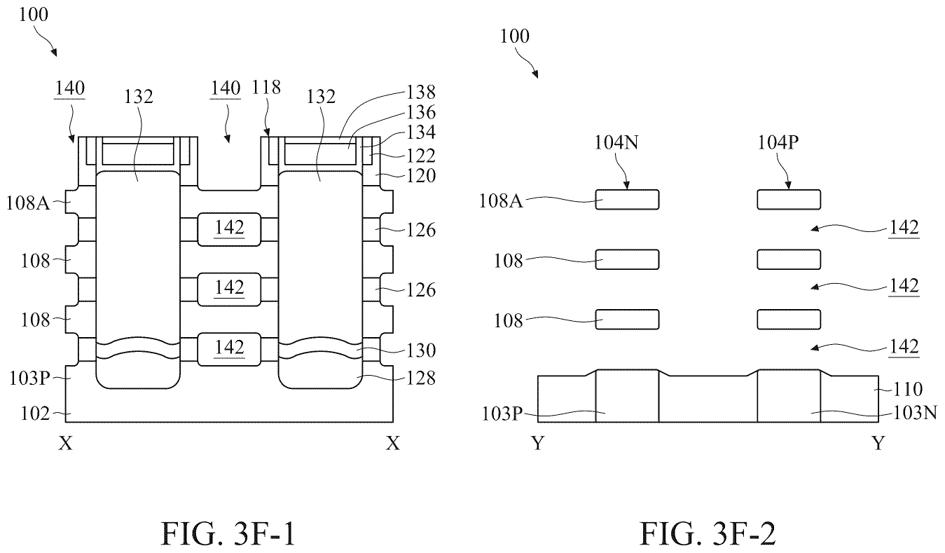

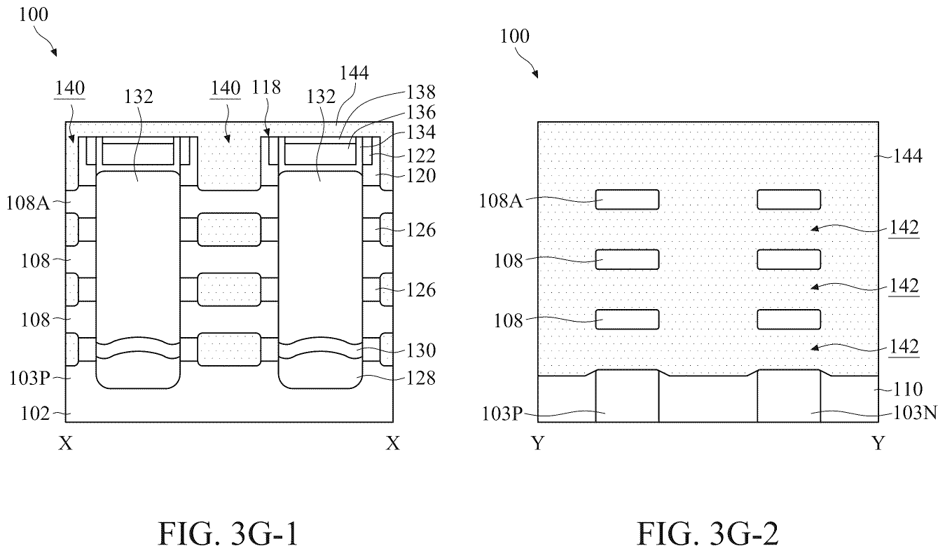

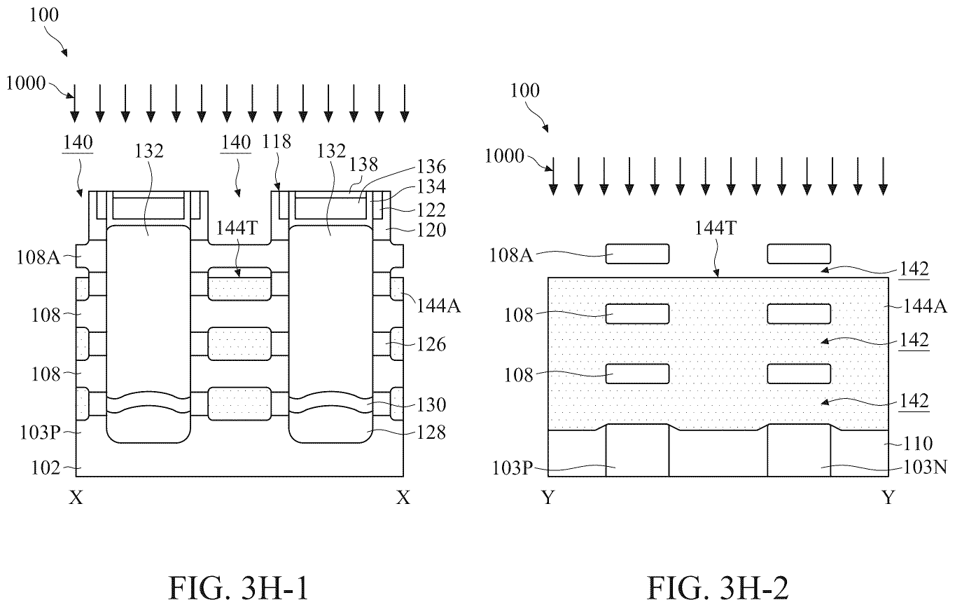

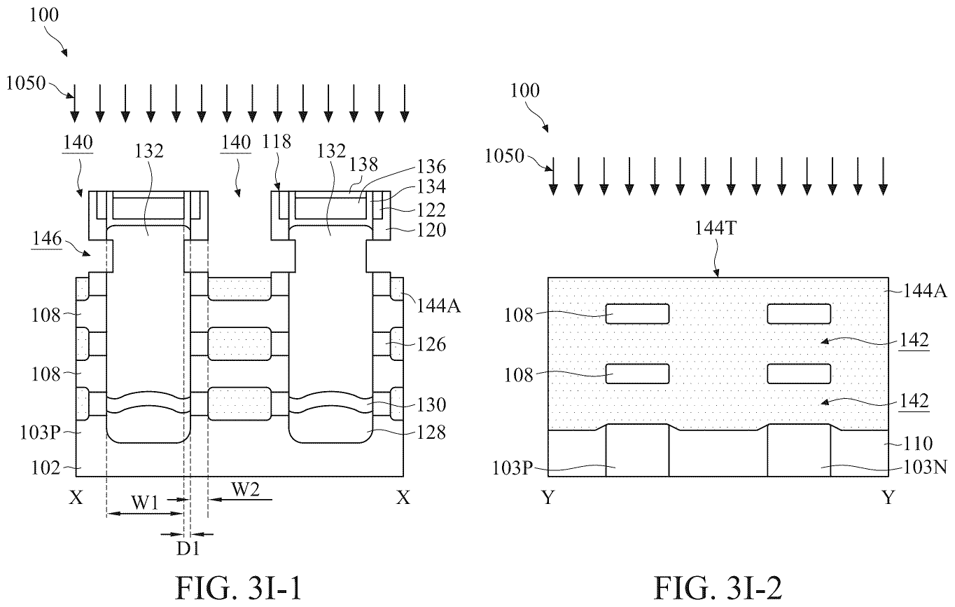

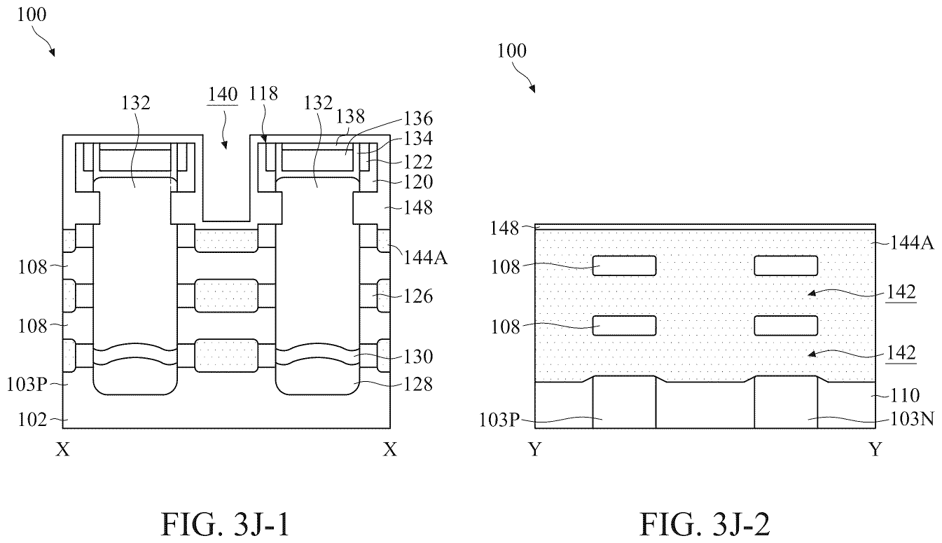

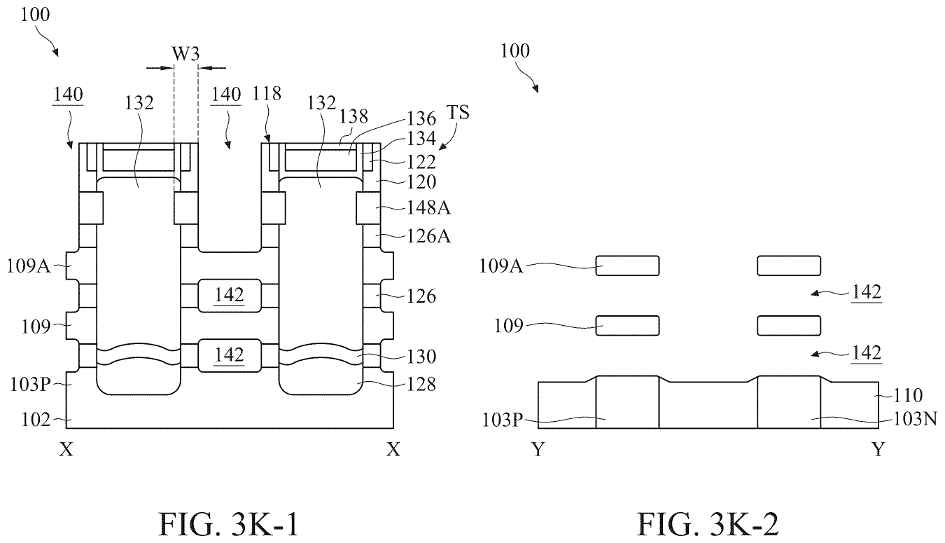

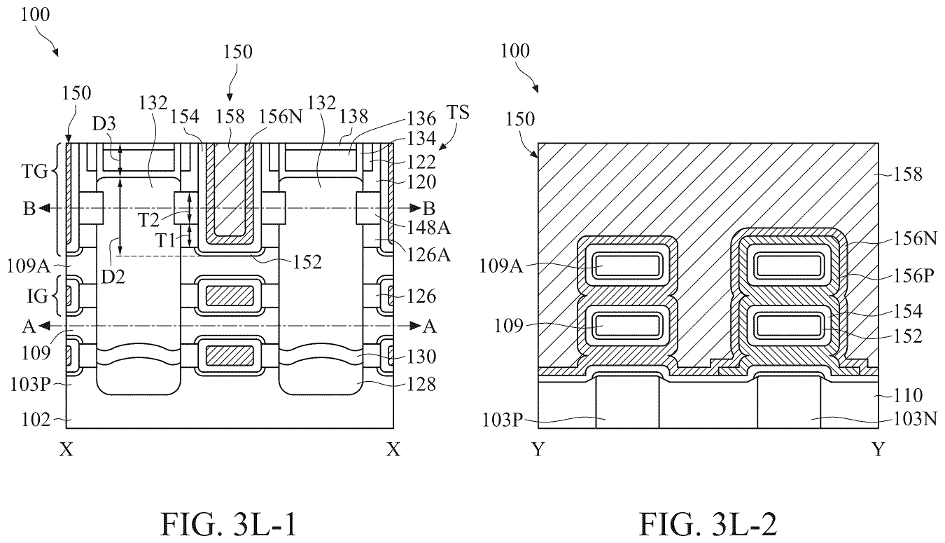

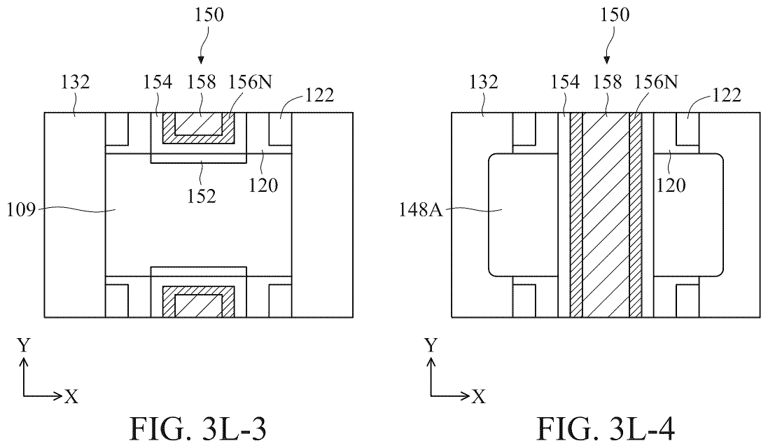

FIGS. 3A-1 through 3I-3 are cross-sectional views illustrating the formation of a semiconductor structure 100 at various intermediate stages, in which FIGS. 3A-1, 3B-1, 3C-1, 3D-1, 3E-1, 3F-1, 3G-1, 3H-1, 3I-1, 3J-1, 3K-1 and 3L-1 correspond to cross-section X-X shown in FIG. 2, and FIGS. 3A-2, 3B-2, 3C-2, 3D-2, 3E-2, 3F-2, 3G-2, 3H-2, 3I-2, 3J-1, 3K-1 and 3L-1 correspond to cross-section Y-Y shown in FIG. 2, in accordance with some embodiments of the disclosure.

FIGS. 3A-1 and 3A-2 illustrate a semiconductor structure 100 after the formation of active regions 104, an isolation structure 110, dummy gate structures 112, and gate spacer layers 118, in accordance with some embodiments. A substrate 102 is provided, as shown in FIGS. 3A-1 and 3A-2, in accordance with some embodiments. The substrate 102 may be a portion of a semiconductor wafer, a semiconductor chip (or die), and the like. some embodiments, the substrate 102 is a silicon substrate.

In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

An n-type well and a p-type well (as shown in FIGS. 1 and 2) are formed in the substrate 102, in accordance with some embodiments. In some embodiments, the n-type well and the p-type well have different electrically conductive types. In some embodiments, the n-type and p-type wells are formed by respective ion implantation processes. In some embodiments, the ion implantation processes may be performed several times with different dosages and different energy intensities. In some embodiments, the ion implantation process may include anti-punch through (APT) implant.

Active regions 104 (including 104N and 104P) are formed over the substrate 102, as shown in FIGS. 3A-1 and 3A-2, in accordance with some embodiments. In some embodiments, the active regions 104N and 104P extend in the X direction. In some embodiments, the active regions 104N and 104P may be the fin structures 104N and 104P in FIG. 1. The formation of the active regions 104N and 104P includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic% to about 50 atomic%, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel layers for the resulting semiconductor devices (such as nanostructure transistors), in accordance with some embodiments.

The formation of the active regions 104N and 104P further includes patterning the epitaxial stack and the underlying n-type and p-type wells using photolithography and etching processes, thereby forming trenches, in accordance with some embodiments. The active regions 104N and 104P protrude from between trenches, in accordance with some embodiments. The p-type well protruding from between the trenches forms the lower fin element 103P of the active region 104N, and the n-type well protruding from between the trenches forms the lower fin element 103N of the active region 104P, in accordance with some embodiments. The remainder of the epitaxial stack (including the semiconductor layers 106 and 108) forms the upper fin elements of the active regions 104N and 104P, in accordance with some embodiments.

In some embodiments, the thickness T1 of each of the first semiconductor layers 106 is in a range from about 3 nm to about 20 nm, such as about 4 nm to about 12 nm. In some embodiments, the thickness T2 of each of the second semiconductor layers 108 is in a range from about 3 nm to about 20 nm, such as about 4 nm to about 12 nm. The thickness T2 of the second semiconductor layers 108 may be greater than, equal to, or less than the thickness T2 of the first semiconductor layers 106, which may depend on the amount of gate materials to be filled in spaces where the first semiconductor layers 106 are removed.

An isolation structure 110 is formed to surround the lower fin elements 103N and 103P, as shown in FIG. 3A-2, in accordance with some embodiments. The isolation structure 110 is configured to electrically isolate active regions 104N and 104P from one another, and is also referred to as shallow trench isolation (STI) feature, in accordance with some embodiments. The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process (e.g., chemical mechanical polishing (CMP), etching back process, or a combination thereof) is performed on the insulating material, in accordance with some embodiments. The insulating material is then recessed by an etching process (such as dry plasma etching and/or wet chemical etching) until the upper fin elements of the active regions 104N and 104P are exposed, in accordance with some embodiments. In some embodiments, the top portions of the lower fin element 103N and 103P may be further exposed from the isolation structure 110, in accordance with some embodiments.

Dummy gate structures 112 are formed across the active regions 104N and 104P and the isolation structure 110, as shown in FIG. 3A-1, in accordance with some embodiments. The dummy gate structures 112 are configured as sacrificial structures and will be replaced with the final gate stacks, in accordance with some embodiments. In some embodiments, the dummy gate structures 112 extend in the Y direction. The dummy gate structures 112 surround the channel regions of the active regions 104, in accordance with some embodiments. The dummy gate structures 112 may be the gate structures 112 shown in FIG. 1.

Each of the dummy gate structures 112 includes a dummy gate dielectric layer 114 and a dummy gate electrode layer 116 over the dummy gate dielectric layer, in accordance with some embodiments. In some embodiments, the dummy gate dielectric layer 114 is conformally formed along the upper fin elements of the active regions 104N and 104P using ALD, CVD, thermal oxidation, physical vapor deposition (PVD), another suitable technique, or a combination thereof. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, and/or HfAlO.

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structures 112 using photolithography and etching processes.

Gate spacer layers 118 are formed along opposite sidewalls of the dummy gate structures 112, as shown in FIG. 3A-1, in accordance with some embodiments. The gate spacer layers 118 extend in the Y direction and across the active regions 104N and 104P and the isolation structure 110, in accordance with some embodiments. The gate spacer layers 118 are used to offset the subsequently formed source/drain features and separate the source/drain features from the gate structure, in accordance with some embodiments.

In some embodiments, the gate spacer layers 118 are formed from one or more continuous dielectric material(s). For example, in some embodiments, the formation of the gate spacer layers 118 includes globally and conformally depositing spacer layers 120 and 122 over the semiconductor structure 100 using ALD, CVD (such as LPCVD, PECVD or HDP-CVD or a combination thereof, followed by an anisotropic etching process, as shown in FIG. 3A-1, in accordance with some embodiments.

In some embodiments, the spacer layers 120 and 122 are made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the spacer layer 120 and the spacer layer 122 are made of different materials and have different dielectric constant values. For example, the spacer layers 120 and 122 are made of SiOCN with different compositions (e.g., different carbon concentrations) and different dielectric constants. In some embodiments, the spacer layers 120 and 122 are the same material.

After the anisotropic etching process, the vertical portions of the spacer layers 120 and 122 that are left remaining on the opposite sides of the dummy gate structures 112 form the gate spacer layers 118, in accordance with some embodiments. In some embodiments, the vertical portions of the spacer layers 120 and 122 may be left on the opposite sides of the active regions 104 and form fin spacer layers.

FIGS. 3B-1 and 3B-2 illustrate a semiconductor structure 100 after the formation of source/drain recesses 124, in accordance with some embodiments. An etching process is performed to recess the source/drain regions of the active regions 104N and 104P, thereby forming source/drain recesses 124, as shown in FIG. 3B-1, in accordance with some embodiments. The etching process may be an anisotropic etching process such as dry plasma etching, an isotropic etching process such as dry chemical etching, remote plasma etching or wet chemical etching, and/or a combination thereof. The gate spacer layers 118 and the dummy gate structures 112 may serve as etch masks such that the source/drain recesses 124 are formed self-aligned on opposite sides of the dummy gate structures 112, in accordance with some embodiments.

FIGS. 3C-1 and 3C-2 illustrate a semiconductor structure 100 after the formation of inner spacer layers 126, in accordance with some embodiments. An etching process is performed to laterally recess, from the source/drain recesses 124, the first semiconductor layers 106 of the active regions 104N and 104P, thereby forming notches, and then inner spacer layers 126 are formed in the notches, as shown in FIG. 3C-1, in accordance with some embodiments. The inner spacer layers 126 abut the recessed side surfaces of the first semiconductor layers 106, in accordance with some embodiments. The inner spacer layers 126 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 126 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the inner spacer layers 126 are formed by depositing a dielectric material to fill the notches using ALD, CVD (such as PECVD, LPCVD or HARP), another suitable technique, or a combination thereof, and the dielectric material outside the notches are then etched away using an anisotropic etching process such as dry plasma etching, an isotropic etching process such as dry chemical etching, remote plasma etching or wet chemical etching, or a combination thereof.

FIGS. 3D-1 and 3D-2 illustrate a semiconductor structure 100 after the formation of semiconductor isolation layers 128, dielectric isolation layers 130, and source/drain features 132, in accordance with some embodiments. Semiconductor isolation layers 128 are optionally grown on the lower fin elements 103N and 103P, as shown in FIG. 3D-1, in accordance with some embodiments. In some embodiments, the semiconductor isolation layers 128 are made of an epitaxial semiconductor material such as silicon, silicon germanium or germanium, formed by MBE, MOCVD, or VPE, another suitable technique, or a combination thereof. In an embodiment, the semiconductor isolation layers 128 are made of non-doped silicon.

Dielectric isolation layers 130 are optionally formed on the semiconductor isolation layers 128, as shown in FIG. 3D-1, in accordance with some embodiments. In some embodiments, the dielectric isolation layers 130 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the dielectric isolation layers 130 are formed a deposition followed by and etching-back processes.

In some embodiments, the sidewalls of the bottommost semiconductor layers 108 are uncovered by the dielectric isolation layers 130. The semiconductor isolation layers 128 and the dielectric isolation layers 130 may be configured to reduce the total cell capacitance, in accordance with some embodiments. In some embodiments, the dielectric isolation layers 130 are selectively formed on the semiconductor isolation layers 128 only over the lower fin element 103P.

Source/drain features 132 are grown from the exposed side surfaces of the second semiconductor layers 108 to fill the source/drain recesses 124 using an epitaxial growth process, as shown in FIG. 3D-1, in accordance with some embodiments. The epitaxial growth process may be MBE, MOCVD, or VPE, or another suitable technique. In some embodiments, the source/drain features 132 are formed on the dielectric isolation layers 130. In some embodiments where the semiconductor isolation layers 128 and the dielectric isolation layers 130 are omitted, the source/drain features 132 are formed on the lower fin elements 103N and 103P.

In some embodiments, the source/drain features 132 are made of any suitable semiconductor material for n-type semiconductor devices (e.g., n-channel nanostructure transistors) or p-type semiconductor devices (e.g., p-channel nanostructure transistors). In some embodiments, the source/drain features 132 are doped. The concentration of the dopant in the source/drain features 132 in a range from about 1×10¹⁹ cm⁻³ to about 6×10²¹ cm⁻³.

In some embodiments the source/drain features 132 are formed in the p-type well, the source/drain features 132 are doped with the n-type dopant during the epitaxial growth process. For example, the n-type dopant may be phosphorous (P) or arsenic (As). The n-type source/drain features 132 are made of semiconductor material such as SiP, SiAs, SiCP, SiC, Si, GaAs, another suitable semiconductor material, or a combination thereof For example, the n-type source/drain features 132 may be the epitaxially grown Si doped with phosphorous to form silicon: phosphor (Si:P) source/drain features and/or arsenic to form silicon: arsenic (Si:As) source/drain feature.

In some embodiments where the source/drain features 132 are formed in the n-type well, the source/drain features 132 are doped with the p-type dopant during the epitaxial growth process. For example, the p-type dopant may be boron (B) or BF₂. The p-type source/drain features 132 are made of semiconductor material such as SiGe, Si, GaAs, another suitable semiconductor material, or a combination thereof. In some embodiments, the p-type source/drain features 132 may be the epitaxially grown SiGe doped with boron (B) to form silicon germanium: boron (SiGe:B) source/drain feature.

FIGS. 3E-1 and 3E-2 illustrate a semiconductor structure 100 after the formation of a contact etching stop layer 134, an interlayer dielectric layer 136 and a dielectric mask layer 138, in accordance with some embodiments. A contact etching stop layer 134 is formed over the semiconductor structure 100 to cover the source/drain features 132, as shown in FIG. 3E-1, in accordance with some embodiments. In some embodiments, the contact etching stop layer 134 is made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the contact etching stop layer 136 and 138 are globally and conformally deposited using ALD, CVD (such as LPCVD, PECVD, HDP-CVD and HARP), another suitable method, and/or a combination thereof

An interlayer dielectric layer 136 is formed over the contact etching stop layer 138, as shown in FIG. 3E-1, in accordance with some embodiments. The interlayer dielectric layer 136 overfills the space between dummy gate structures 112, in accordance with some embodiments. In some embodiments, the interlayer dielectric layer 136 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the dielectric material for the interlayer dielectric layer 136 is deposited using such as CVD (such as HDP-CVD, PECVD, HARP or FCVD), another suitable technique, or a combination thereof.

The dielectric materials for the contact etching stop layer 134 and the interlayer dielectric layer 136 above the top surface of the dummy gate electrode layer 116 are removed using such as CMP, in accordance with some embodiments. Afterward, the interlayer dielectric layer 136 is recessed to form trenches (now shown), and a dielectric mask layer 138 is formed to fill the trenches, as shown in FIG. 3E-1. The dielectric mask layer 138 is configured to protect the interlayer dielectric layer 136 in the following etching processes, and may have a different etching selectivity than the interlayer dielectric layer 136, in accordance with some embodiments.

In some embodiments, the dielectric mask layer 138 is made of a dielectric material, such as silicon nitride (SiN), silicon oxynitride (SiON), silicon oxide (SiO₂), oxygen-doped silicon carbide (SiC: O), oxygen-doped silicon carbonitride (Si(O)CN), silicon carbide (SiC), or another suitable dielectric material. In some embodiments, the formation of the dielectric mask layer 138 includes a deposition process, followed by a removal process (e.g., etching-back or CMP process).

FIGS. 3F-1 and 3F-2 illustrate the formation of gate trenches 140 and gaps 142, in accordance with some embodiments. The dummy gate structures 112 are removed using one or more etching processes (e.g., an anisotropic etching process such as dry plasma etching, an isotropic etching process such as dry chemical etching, remote plasma etching or wet chemical etching, and/or a combination thereof) to form gate trenches 140 between the gate spacer layers 118, as shown in FIGS. 3F-1 and 3F-2, in accordance with some embodiments. In some embodiments, the gate trenches 140 expose the channel regions of the active regions 104N and 104P. In some embodiments, the gate trenches 140 also expose the sidewalls of the gate spacer layers 118 facing the channel regions.

Afterward, an etching process is performed to remove the first semiconductor layers 106 of the active regions 104N and 104P to form gaps 142, as shown in FIGS. 3F-1 and 3F-2, in accordance with some embodiments. The etching process may be an anisotropic etching process such as dry plasma etching, an isotropic etching process such as dry chemical etching, remote plasma etching or wet chemical etching, and/or a combination thereof. The inner spacer layers 126 may be used as an etching stop layer in the etching process, which may protect the source/drain features 132 from being damaged. In some embodiments, the gaps 142 also expose the sidewalls of the inner spacer layers 126 facing the channel regions.

After the etching process, the four main surfaces (the top surface, the bottom surface, and two side surfaces) of the second semiconductor layers 108 are exposed, in accordance with some embodiments. The topmost second semiconductor layers 108 are denoted as 108A, and will be entirely or partially removed. This will be discussed in detail below.

FIGS. 3G-1 through 3I-3 illustrate a patterning process of channel layers. The patterning process is used to globally reduce the number of channel layers in all device regions, or locally reduce the number of channel layers in specific device regions. For example, the semiconductor structure 100 may include several device regions such as a logic device region, a high-performance device region, a low-power consumption device region, a memory device region, an analog region, a peripheral region, and/or a combination thereof, in accordance with some embodiments. In an embodiment where the total cell capacitance may be of concern for the low-power consumption device region, the patterning process of channel layers discussed below may be performed locally on the low-power consumption device region of the semiconductor structure 100.

FIGS. 3G-1 and 3G-2 illustrate the formation of mask layer 144, in accordance with some embodiments. A mask layer 144 is formed over the semiconductor structure 100 to fill the gate trenches 140 and the gaps 142, as shown in FIGS. 3G-1 and 3G-2, in accordance with some embodiments. In some embodiments, the mask layer 144 is made of BARC material (such as an inorganic material or an organic material (e.g., polymer, oligomer, or monomer)), and/or photoresist material, which may be formed using spin-on coating process or a CVD process.

In some embodiments, the mask layer 144 is made silicon-containing dielectric material (e.g., silicon nitride (SiN), silicon oxynitride (SiON), silicon oxide (SiO₂), silicon oxycarbide (SiOC), silicon carbide (SiC), or oxygen-doped silicon carbonitride (Si(O)CN)); a metal oxide dielectric such as Al₂O₃, LaO, HfO₂, Ta₂O₅, TiO₂, ZrO₂, or Y₂O₃; another suitable mask material; or a combination thereof, which may be formed using ALD or CVD.

FIGS. 3H-1 and 3H-2 illustrate an etching process 1000, in accordance with some embodiments. An etching process 1000 is performed on the semiconductor structure 100 to recess the mask layer 144, as shown in FIGS. 3H-1 and 3H-2, in accordance with some embodiments. The recessed mask layer 144 is denoted as 144A. The etching process 1000 may be an anisotropic etching process such as dry plasma etching, an isotropic etching process such as dry chemical etching, remote plasma etching or wet chemical etching, and/or a combination thereof.

After the etching process 1000, the topmost second semiconductor layers 108A are entirely exposed from the mask layer 144A, while the underlying second semiconductor layers 108 remain covered by the mask layer 144A, in accordance with some embodiments. That is, in some embodiments, the top surface 144T of the mask layer 144A is located in a position between the bottom surfaces of the topmost second semiconductor layers 108A and the top surfaces of the second topmost second semiconductor layers 108. In some embodiments, the etching process 1000 is globally performed on all the device regions of the substrate 102.

In some embodiments where the patterning process of the channel layers is locally performed in specific device regions (e.g., the low-power consumption device region), before the etching process 1000, a patterned photoresist material (not shown) is formed over the mask layer 144 (FIGS. 3G-1 and 3G-2) using a photolithography process. For example, the photolithography process may include forming a photoresist material, performing a pre-exposure baking process, performing an exposure process using a mask (or a reticle), performing a post-exposure baking process, and performing a developing process. In an embodiment, the patterned photoresist material exposes the low-power consumption device region while covering other device regions covered. The patterned photoresist material may be removed in the etching process 1000, or by an additional process (e.g., ashing, etching or wet stripping process).

FIGS. 3I-1 and 3I-2 illustrate an etching process 1050, in accordance with some embodiments. An etching process 1050 is performed on the semiconductor structure 100 to remove the topmost second semiconductor layers 108A, as shown in FIGS. 3I-1 and 3I-2, in accordance with some embodiments. The etching process 1050 may be an anisotropic etching process such as dry plasma etching, an isotropic etching process such as dry chemical etching, remote plasma etching or wet chemical etching, and/or a combination thereof. In some embodiments, the mask layer 144A protects the underlying second semiconductor layers 108 from being damaged in the etching process 1050.

In some embodiments, the topmost second semiconductor layers 108A are entirely removed, thereby forming recesses 146 directly under the gate spacer layers 118 and exposing the source/drain features 132. The etching process 1050 may include an over-etch step to make sure that the second semiconductor layers 108 are entirely removed, in accordance with some embodiments. In some embodiments, the source/drain features 132 are laterally recessed by a dimension D1 in the over-etch step. In some embodiments, the dimension D1 in the X direction is less than 5 nm.

In some embodiments, the source/drain feature 132 has a width (dimension in the X direction) W1 in a range from about 5 nm to about 30 nm. In some embodiments, the ratio (D1/W1) of the dimension D1 to the width W1 is less than 0.25. If the ratio is too large, the contact resistance of the resulting semiconductor device may increase. In some embodiments, the inner spacer layer 126 has a width (dimension in the X direction) W2 in a range from about 1 nm to about 10 nm. In some embodiments, the ratio of the dimension D1 to the width W2 is in a range from about 0.5 to about 1.

In some embodiments, the source/drain features 132 may be substantially unrecessed (i.e., D1 is approximately zero) in the over-etch step. In some embodiments, the topmost second semiconductor layers 108A are partially removed, and the remaining portions of the topmost second semiconductor layers 108A are left directly under the gate spacer layers 118.

FIGS. 3J-1 and 3J-2 illustrate the formation of a dielectric material 148, in accordance with some embodiments. A dielectric material 148 is formed over the semiconductor structure 100 to overfill the recesses 146, as shown in FIGS. 3J-1 and 3J-2, in accordance with some embodiments. In some embodiments, the dielectric material 148 is made of low-k dielectric material (e.g., with a k value less than 7.9), such as silicon oxide (SiO₂), silicon nitride (SiN), silicon oxynitride (SiON), silicon carbon nitride (SiCN), silicon oxycarbonitride (SiOCN), oxygen-doped silicon carbonitride (Si(O)CN), and/or a combination thereof. In some embodiments, the dielectric material 148 is deposited using ALD, CVD (such as PECVD, LPCVD or HARP), another suitable technique, or a combination thereof.

FIGS. 3K-1 and 3K-2 illustrate an etching process, in accordance with some embodiments. An etching process is performed to remove the dielectric material 148 outside the recesses 146, as shown in FIGS. 3K-1 and 3K-2, in accordance with some embodiments. The portion of the dielectric material 148 remains in the recesses 146 and serve as dielectric spacer features 148A, in accordance with some embodiments. In some embodiments, the etching process may be an anisotropic etching process such as dry plasma etching, an isotropic etching process such as dry chemical etching, remote plasma etching or wet chemical etching, or a combination thereof.

The mask layer 144A is then removed using an etching process, in accordance with some embodiments. In some embodiments, the etching process may be an anisotropic etching process such as dry plasma etching, an isotropic etching process such as dry chemical etching, remote plasma etching or wet chemical etching, or a combination thereof.

In some embodiments, the sidewalls of the dielectric spacer features 148A facing the channel region are substantially vertically aligned with the sidewalls of the gate spacer layer 118 facing the channel region. In some embodiments, the width W3 (the dimension in the X direction) of the dielectric spacer features 148A is in a range from about 1 nm to about 15 nm. In some embodiments, the width W3 of the dielectric spacer features 148A is equal to or wider than the width W2 of the inner spacer layer 126.

The dielectric spacer feature 148A may avoid the source/drain features and the gate stack from being in direct contact, in accordance with some embodiments. The dielectric spacer feature 148A includes a portion extending into the source/drain feature 132, in accordance with some embodiments. In some embodiments, the gate spacer layers 118 (including the spacer layers 120 and 122), the dielectric spacer features 148A and the topmost inner spacer layers 126A collectively serve as top spacer structures TS.

The remaining second semiconductor layers 108 serve as nanostructures 109 that function as channels of the resulting semiconductor device (e.g., nanostructure transistors such as GAA FET), in accordance with some embodiments. The topmost nanostructures 109 (i.e., second topmost second semiconductor layers 108) are denoted as 109A. The top spacer structures TS are located above the topmost nanostructures 109A, in accordance with some embodiments.

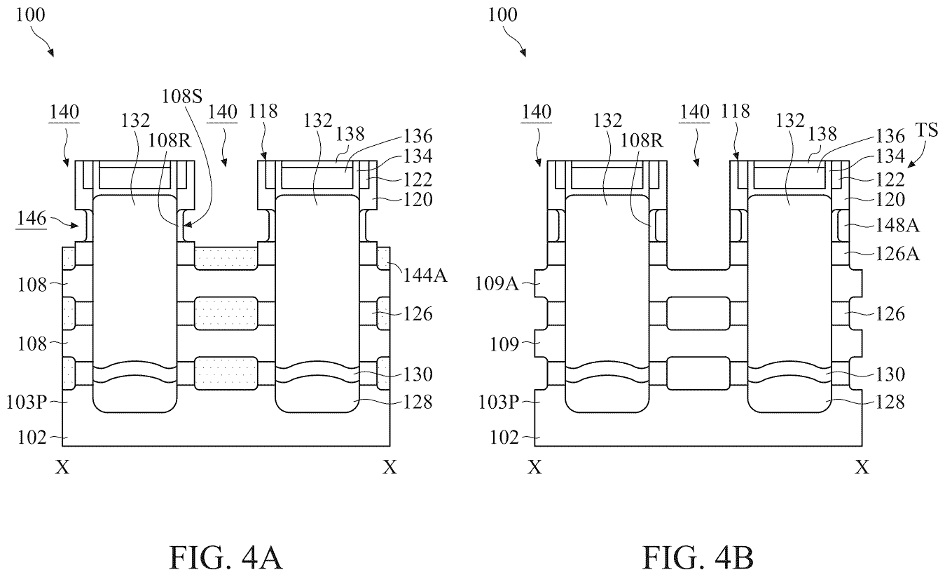

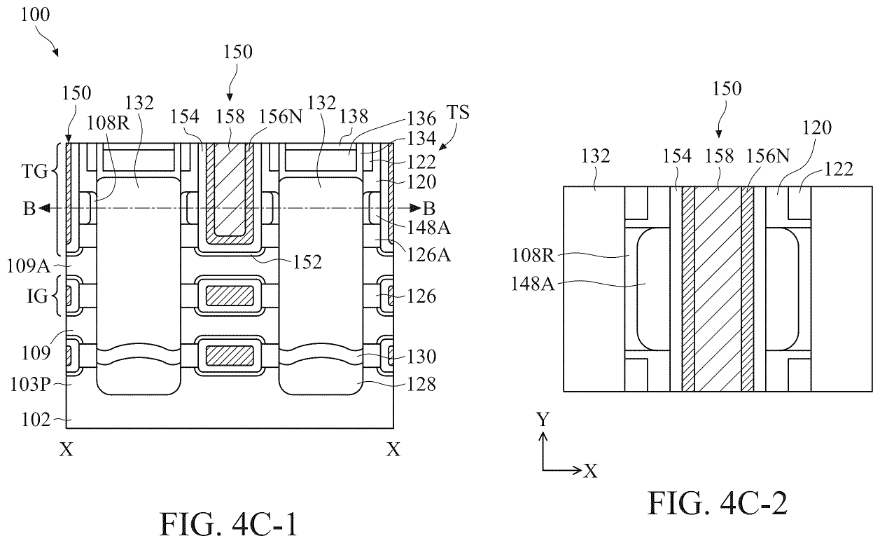

FIGS. 3L-1 and 3L-2 illustrate a semiconductor structure 100 after the formation of final gate stacks 150, in accordance with some embodiments. FIGS. 3L-3 and 3L-4 are plan views illustrating the semiconductor structure 100 cutting through plan A-A and plan B-B of FIG. 3L-1, in accordance with some embodiments.

Final gate stacks 150 are formed in the gate trenches 140 and gaps 142, thereby wrapping around the nanostructures 109 (including 109A), as shown in FIGS. 3L-1 to 3L-4, in accordance with some embodiments. In some embodiments, the final gate stacks 150 extend in the Y direction. In some embodiments, each of the final gate stacks 150 includes an interfacial layer 152, a gate dielectric layer 154 and a metal gate electrode layer.

The interfacial layer 152 is formed on the exposed surfaces of the nanostructures 109 and the exposed surfaces of the lower fin elements 103N and 103P, in accordance with some embodiments. The interfacial layer 152 wraps around the nanostructures 109, in accordance with some embodiments. In some embodiments, the interfacial layer 152 is made of a chemically formed silicon oxide. In some embodiments, the interfacial layer 152 is nitrogen-doped silicon oxide. In some embodiments, the interfacial layer 152 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 109 and the lower fin elements 103N and 103P is oxidized to form the interfacial layer 152, in accordance with some embodiments.

A gate dielectric layer 154 is formed conformally along the interfacial layer 152 to wrap around the nanostructures 109, in accordance with some embodiments. The gate dielectric layer 154 is further formed along the top surface of the isolation structure 110 and the sidewalls of the top spacer structures TS and the inner spacer layers 126 facing the channel region, in accordance with some embodiments. The gate dielectric layer 154 may be a high-k dielectric layer. In some embodiments, the high-k dielectric layer is dielectric material with a high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Si₃N₄, oxynitrides (SiON), a combination thereof, or another suitable material. The high-k dielectric layer may be deposited using ALD, PVD, CVD, and/or another suitable technique.

The metal gate electrode layer is formed to fill the remainders of the gate trenches 140 and gaps 142, in accordance with some embodiments. In some embodiments, the metal gate electrode layer is made of more than one conductive material(s), for example, a p-type work function layer 156P, an n-type work function layer 156N and a metal fill layer 158, as shown in FIGS. 3L-1 to 3L-4. In some embodiments, the p-type work function layer 156P is formed on the gate dielectric layer 154 in the n-type well. In some embodiments, the n-type work function layer 156N is formed on the gate dielectric layer 154 in the p-type well and on the p-type work function layer 156P in the n-type well. In some embodiments, the work function metal layers 156P and 156N have selected work functions to enhance the device performance (e.g., threshold voltage) for n-channel FETs or p-channel FETs.

For example, the p-type work function metal layer 156P is made of TiN, WN, WCN, TaN, Ru, Co, W, or another suitable p-type work function metal, and the n-type work function layer 156N is made of Ti, Ag, Al, TiAl, TiAlN, TiAlC, TaAl, TaC, TaCN, TaSiN, TaAlC, Mn, Zr, or another suitable n-type work function metal. The metal fill layer 158 may be made of W, Co, or Ru. These gate electrode materials may be deposited using ALD, PVD, CVD, e-beam evaporation, or another suitable technique.

A planarization process such as CMP may be performed on the semiconductor structure 100 to remove the materials of the gate dielectric layer 154 and the metal gate electrode layer formed above the upper surface of the dielectric mask layer 138, in accordance with some embodiments.

The final gate stack 150 wrapped around the nanostructures 109 is combined with the neighboring source/drain features 132 to form nanostructure transistors. In some embodiments, the nanostructure transistors 109 formed over the lower fin element 103P (in the p-type well) are n-channel nanostructure transistors, and the nanostructure transistors 109 formed over the lower fin element 103N (in the n-type well) are p-channel nanostructure transistors. The final gate stacks 150 may engage the channel region so that current can flow between the source/drain features 132 during operation.

The portions of the final gate stacks 150 formed above the topmost nanostructures 109A are referred to as top gates TG, in accordance with some embodiments. The top gates TG are laterally sandwiched between the top spacer structures TS, in accordance with some embodiments. The portions of the final gate stacks 150 formed vertically between the nanostructures 109 and between the bottommost nanostructures 109 and the lower fin element 103P (or 103N) are referred to as inner gates IG, in accordance with some embodiments. The inner gates IG are laterally sandwiched between the inner spacer layers 126, in accordance with some embodiments.

The distance D2 from the top of the source/drain feature 132 to the bottom surface of the top gate TG in the Z direction is in a range from about 5 nm to about 50 nm. In some embodiments, the distance D2 is greater than the sum of the thickness T2 of the nanostructure 109 (and the thickness of dielectric spacer features 148A) and the thickness T1 of the inner spacer layer 126 (or 126A). In some embodiments, the sum of the thickness T1 and the thickness T2 is in a range from about 5 nm to about 30 nm. The distance D3 from the top of the source/drain feature 132 to the top surface of the top gate TG in the Z direction is in a range from about 5 nm to about 50 nm. In some embodiments, the distance D3 is less than the distance D2, as shown in FIG. 3L-1. In some embodiments, the ratio of the distance D3 to the distance D2 is in a range from about 0.1 to about 0.5. In some embodiments, the distance D3 is equal to or greater than the distance D2.

In accordance with some embodiments, the patterning process of channel layers reduces the number of channel layers of a transistor, e.g., from 3 channels to 2 channels, which may significantly reduce the capacitance of channel (Cch), which exists in the channel layer between the top gate TG and the inner gate IG and between the inner gates IG, and the capacitance of junction overlap (Cov), which exists in the LDD (lightly-doped drain) region between the final gate stack 150 and the source/drain feature 132. For example, each of the capacitance of channel and the capacitance of junction overlap may be reduced by about 30-40%. Therefore, the performance of the resulting semiconductor device may be enhanced, e.g., reduction in power consumption, and/or faster speed.

Although the embodiments shown in FIGS. 3A-1 through 3L-2 illustrate the patterning process of channel layers that reduces one channel layer, but the embodiments are not limited thereof. In some embodiments where the number the second semiconductor layer 108 is greater than three, e.g., 4-10, the patterning process of channel layers may reduce more than one channel layer, e.g., 2-5 channel layers.

In addition, because the topmost second semiconductor layers 108A are entirely removed and the dielectric spacer features 148A are formed to separate the source/drain feature 132 and the final gate stack 150, the total cell capacitance may be further reduced. Therefore, the performance of the resulting semiconductor device may be further enhanced. Furthermore, by precisely controlling the parameter of the etching process 1050, the recessing dimension D1 (FIG. 3I-1) may be low, and thus there is substantially no increase in contact resistance.

In addition, because the patterning process of channel layers is performed after the dummy gate structures 112 are removed, the upstream processes (e.g., the formation and morphology of the source/drain features, etc.) are not impacted. As a result, the downstream process (e.g., the formation of the contact plug) may be substantially unimpacted.

It is understood that the semiconductor structure 100 may undergo further CMOS processes to form various features over the semiconductor structure 100, such as a multilayer interconnect structure (e.g., contacts to gate and/or source/drain features, vias, lines, inter metal dielectric layers, passivation layers, etc.).

FIGS. 4A to 4C-1 are cross-sectional views illustrating the formation of a semiconductor structure 100 at various intermediate stages, in accordance with some embodiments of the disclosure. FIG. 4C-2 are plan views illustrating the semiconductor structure 100 cutting through plan B-B of FIG. 4C-1, in accordance with some embodiments. The embodiments of FIGS. 4A to 4C-1 are similar to the embodiments of FIGS. 3A-1 to 3L-2 except that the topmost second semiconductor layers 108A are partially removed.

Continuing from FIGS. 3I-1 and 3I-3, the etching process 1050 partially removes the topmost second semiconductor layers 108A and cut each topmost second semiconductor layers 108A into two portions, as shown in FIG. 4A, in accordance with some embodiments. The remaining portions of the topmost second semiconductor layers 108A are left directly under the gate spacer layers 118 and referred to as semiconductor spacer features 108R, as shown in FIG. 4A, in accordance with some embodiments. In some embodiments, the sidewalls 108S of the semiconductor spacer features 108R facing the channel region are indented from the sidewalls of the gate spacer layers 118 facing the channel region. In some embodiments, the sidewalls of the semiconductor spacer features 108R facing the channel region may be curved, e.g., concaved.

The steps described above in FIGS. 3J-1 to 3K-2 are performed, thereby forming the dielectric spacer features 148A and removing the mask layer 144A, as shown in FIG. 4B, in accordance with some embodiments. In some embodiments, the gate spacer layers 118 (including the spacer layers 120 and 122), the dielectric spacer features 148A, the semiconductor spacer features 108R and the topmost inner spacer layers 126A collectively serve as top spacer structures TS.

The steps described above in FIGS. 3L-1 and 3L-2 are performed, thereby forming the final gate stacks 150, as shown in FIGS. 4C-1 and 4C-2, in accordance with some embodiments. In accordance with some embodiments, the topmost second semiconductor layers 108A are not entirely removed, which may prevent the source/drain features 132 from being laterally recessing. As a result, the processing difficulty of the etching process 1050 may be reduced. Therefore, the total cell capacitance may be sufficiently reduced while the increase in the contact resistance may be of less concern.

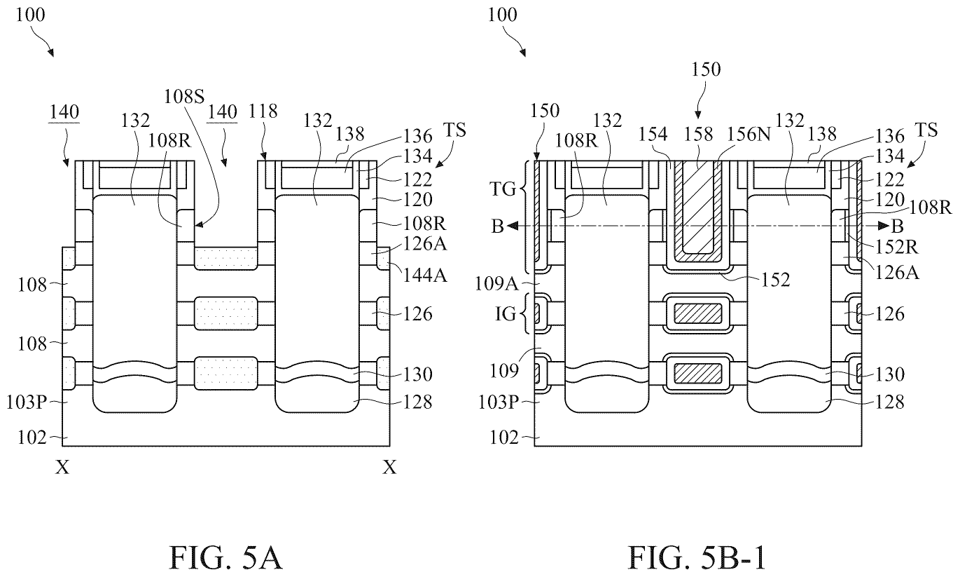

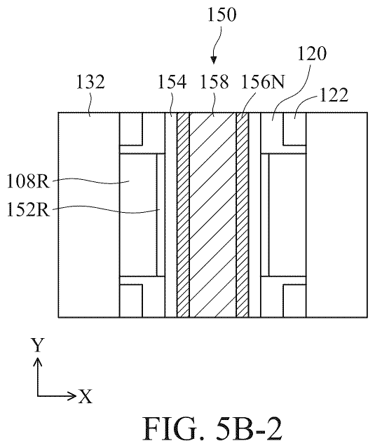

FIGS. 5A and 5B-1 are cross-sectional views illustrating the formation of a semiconductor structure 100 at various intermediate stages, in accordance with some embodiments of the disclosure. FIG. 5B-2 are plan views illustrating the semiconductor structure 100 cutting through plan B-B of FIG. 5B-1, in accordance with some embodiments. The embodiments of FIGS. 5A and 5B-1 are similar to the embodiments of FIGS. 3A-1 to 3L-2 except that the topmost second semiconductor layers 108A are partially removed.

Continuing from FIGS. 3I-1 and 3I-3, the etching process 1050 partially removes the topmost second semiconductor layers 108A and cuts each topmost second semiconductor layers 108A into two portions, as shown in FIG. 5A, in accordance with some embodiments. The remaining portions of the topmost second semiconductor layers 108A are left directly under the gate spacer layers 118 and referred to as semiconductor spacer features 108R, as shown in FIG. 5A, in accordance with some embodiments.

In some embodiments, the sidewalls 108S of the semiconductor spacer features 108R facing the channel region are substantially vertically aligned with the sidewalls of the gate spacer layers 118 facing the channel region. In some embodiments, the sidewalls 108S of the semiconductor spacer features 108R are vertically extending flat surfaces. In some embodiments, the sidewalls of the semiconductor spacer features 108R facing the channel region may be curved, e.g., concaved. In some embodiments, the gate spacer layers 118 (including the spacer layers 120 and 122), the semiconductor spacer features 108R and the topmost inner spacer layers 126A collectively serve as top spacer structures TS.

The steps described above in FIGS. 3L-1 and 3L-2 are performed, thereby forming the final gate stacks 150, as shown in FIGS. 5B-1 and 5B-2, in accordance with some embodiments. In some embodiments, in the one or more cleaning processes for forming the interfacial layer 152, the semiconductor material from the semiconductor spacer features 108R is also oxidized to form an oxide layer 152R, as shown in FIGS. 5B-1 and 5B-2, in accordance with some embodiments.

In accordance with some embodiments, because the topmost second semiconductor layers are not entirely removed, which may prevent the source/drain features 132 from being laterally recessing. As a result, the processing difficulty of the etching process 1050 may be reduced. Therefore, the total cell capacitance may be sufficiently reduced while the increase in the contact resistance may be of less concern.

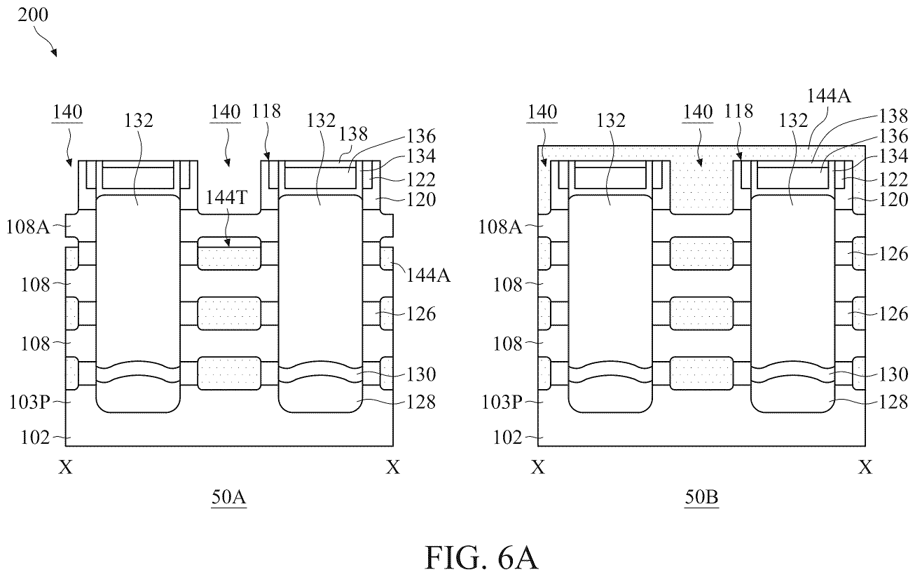

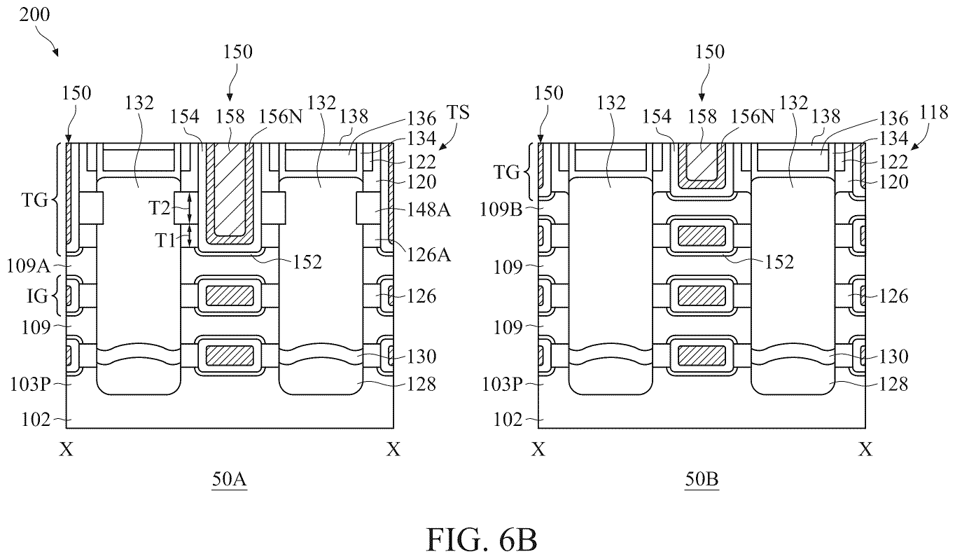

FIGS. 6A and 6B are cross-sectional views illustrating the formation of a semiconductor structure 200 at various intermediate stages, in accordance with some embodiments of the disclosure. The embodiments of FIGS. 6A and 6B are similar to the embodiments of FIGS. 3A-1 to 3L-2 except that the patterning process of channel layers is locally performed on a device region 50A.

In some embodiments, the semiconductor structure 200 includes a first device region 50A and a second device region 50B. In some embodiments, the device in the first device region 50A may focus more on the low power consumption, while the device in the first device region 50B may focus more on high on-state current. The mask layer 144 is patterned using the photolithography process and an etching process (e.g., the etching process 1000 of FIGS. 3H-1 and 3H-2), in accordance with some embodiments. The patterned mask layer 144A covers all of the second semiconductor layers 108 in the device region 50B, and exposes the topmost second semiconductor layers 108A in the device region 50A, as shown in FIG. 6A, in accordance with some embodiments.

Afterward, an etching process 1050 (FIGS. 3I-1 and 3I-2) is performed on the semiconductor structure 200, thereby removing the topmost second semiconductor layers 108A in the device region 50A to form recesses 146, in accordance with some embodiments. The patterned mask layer 144A is removed, in accordance with some embodiments. The steps described above in FIGS. 3J-1 to 3L-2 are performed so that the dielectric spacer features 148A are formed in the recesses 146 in the device region 50A, and the final gate stacks 150 are formed in the device regions 50A and 50B, as shown in FIG. 6B, in accordance with some embodiments.

The topmost nanostructures 109 in the device region 50B are denoted as 109B. In some embodiments, the topmost nanostructures 109B are located at a higher position than the topmost nanostructure 109A. In some embodiments, the top gates TS in the device region 50B is shorter than the top gates TS in the device region 50A.

Although the embodiments shown in FIGS. 6A and 6B illustrate that the number of channel layers in the device region 50A is one less than the number of channel layers in the device region 50B, but the embodiments are not limited thereof. In some embodiments where the number the second semiconductor layer 108 is greater than three, e.g., 4-10, the number of channel layers in the device region 50A is 2 to 5 less than the number of channel layers in the device region 50B.

As described above, the patterning process of channel layers is performed to globally reduce the number of channel layers in all device regions, or locally reduce the number of channel layers in specific device regions. Therefore, the total cell capacitance of the resulting semiconductor device may be sufficiently reduced, thereby improving the power consumption.

Embodiments of a semiconductor structure and the method for forming the same may be provided. The method for forming the semiconductor structure includes removing sacrificial layers of an active region, at least partially removing the topmost channel layer of the active region, and forming a gate stack to surround the remaining channel layers. Therefore, the performance of the resulting semiconductor device may be improved, in accordance with some embodiments.

In some embodiments, a method for forming a semiconductor structure is provided. The method includes forming a first active region in which sacrificial layers and channel layers are alternately stacked. A topmost one of the channel layers is a first channel layer. The method further includes forming a first source/drain feature on the first active region, removing the sacrificial layers of the first active region to form first gaps, at least partially removing the first channel layer of the first active region, and forming a first gate stack to fill the first gaps.

In some embodiments, a method for forming a semiconductor structure is provided. The method includes forming an active region over a substrate. The active region includes a first channel layer, a sacrificial layer over the first channel layer, and a second channel layer over the sacrificial layer. The method further includes removing the sacrificial layer, forming a patterned mask layer to surround a first channel layer while exposing the second channel layer, etching the second channel layer, removing the patterned mask layer, and forming a gate stack to surround the first channel layer.

In some embodiments, a semiconductor structure is provided. The semiconductor structure includes a first group of nanostructures, a first source/drain feature adjoining the first group of nanostructures, and a first gate stack wrapping around the first group of nanostructures. The first gate stack includes a first inner gate between a first nanostructure and a second nanostructure in the first group of nanostructures and a first top gate above the first group of nanostructures. In a vertical direction, a first distance between a bottom of the first top gate and a top of the first source/drain feature is greater than a thickness of the first nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first active region in which sacrificial layers and channel layers are alternately stacked, wherein a topmost one of the channel layers is a first channel layer;
forming a first source/drain feature on the first active region;
removing the sacrificial layers of the first active region to form first gaps;
at least partially removing the first channel layer of the first active region; and
forming a first gate stack to fill the first gaps.

2. The method for forming the semiconductor structure as claimed in claim 1, wherein at least partially removing the first channel layer comprises:
forming a mask layer to surround the channel layers;
etching the mask layer to expose the first channel layer; and
etching the first channel layer.

3. The method for forming the semiconductor structure as claimed in claim 2, wherein a second topmost one of the channel layers is a second channel layer, and after etching the mask layer, a top surface of the mask layer is located between a bottom surface of the first channel layer and a top surface of the second channel layer.

4. The method for forming the semiconductor structure as claimed in claim 1, wherein the first channel layer is removed to expose the first source/drain feature.

5. The method for forming the semiconductor structure as claimed in claim 4, further comprising:
forming a dielectric layer on an exposed surface of the first source/drain feature after at least partially removing the first channel layer and before forming the gate stack to fill the first gaps.

6. The method for forming the semiconductor structure as claimed in claim 1, further comprising:
forming a dummy gate structure across the first active region;
forming gate spacer layers on opposite sides of the dummy gate structure; and
removing the dummy gate structure, wherein after at least partially removing the first channel layer, remaining portions of the first channel layer are left directly under the gate spacer layers.

7. The method for forming the semiconductor structure as claimed in claim 6, further comprising:
forming dielectric layers on remaining portions of the first channel layer after at least partially removing the first channel layer and before forming the gate stack to fill the first gaps.

8. The method for forming the semiconductor structure as claimed in claim 6, wherein the remaining portions of the first channel layer have concave side surfaces.

9. The method for forming the semiconductor structure as claimed in claim 1, further comprising:
forming a second active region in which the sacrificial layers and the channel layers are alternately stacked;
forming a second source/drain feature on the second active region;
removing the sacrificial layers of the second active region to form second gaps;
forming a patented mask layer to cover the channel layers of the second active region while exposing the first channel layer of the first active region;
removing the patented mask layer after at least partially removing the first channel layer of the first active region; and
forming a second gate stack to fill the second gaps.

10. A method for forming a semiconductor structure, comprising:
forming an active region over a substrate, wherein the active region includes a first channel layer, a sacrificial layer over the first channel layer, and a second channel layer over the sacrificial layer;
removing the sacrificial layer;
forming a patterned mask layer to surround a first channel layer while exposing the second channel layer;
etching the second channel layer;
removing the patterned mask layer; and
forming a gate stack to surround the first channel layer.

11. The method for forming the semiconductor structure as claimed in claim 10, wherein the patterned mask layer protects the first channel layer from being etched while the second channel layer is being etched.

12. The method for forming the semiconductor structure as claimed in claim 10, further comprising:
etching the active region to form a first recess; and
forming a source/drain feature in the first recess, wherein the second channel layer is etched to expose the source/drain feature.

13. The method for forming the semiconductor structure as claimed in claim 12, further comprising:
laterally recessing the source/drain feature to form a second recess; and
forming a dielectric layer to fill the second recess.

14. The method for forming the semiconductor structure as claimed in claim 10, wherein the first channel layer and the second channel layer are made of silicon, and the sacrificial layer is made of silicon germanium.

15. A semiconductor structure, comprising:
a first group of nanostructures;
a first source/drain feature adjoining the first group of nanostructures; and
a first gate stack wrapping around the first group of nanostructures, wherein:
the first gate stack includes a first inner gate between a first nanostructure and a second nanostructure in the first group of nanostructures and a first top gate above the first group of nanostructures, and
in a vertical direction, a first distance between a bottom of the first top gate and a top of the first source/drain feature is greater than a thickness of the first nanostructure.

16. The semiconductor structure as claimed in claim 15, further comprising:
a top spacer structure above the first group of nanostructures and between the first source/drain feature and the first top gate, wherein the top spacer structure includes a portion extending into the first source/drain feature.

17. The semiconductor structure as claimed in claim 15, further comprising:
a top spacer structure above the first group of nanostructures and between the first source/drain feature and the first top gate, wherein:
the top spacer structure includes a lower spacer layer, a first middle spacer layer above the lower spacer layer, and an upper spacer layer above the first middle spacer layer, and
the first middle spacer layer is made of a semiconductor material, and
the lower spacer layer and the upper spacer layer are made of a dielectric material.

18. The semiconductor structure as claimed in claim 16, wherein the top spacer structure further includes a second middle spacer layer between the first middle spacer layer and the first top gate, and the second middle spacer is made of a dielectric material.

19. The semiconductor structure as claimed in claim 15, further comprising:
an inner spacer layer between the first nanostructure and the second nanostructure and between the first source/drain feature and the first inner gate, wherein in the vertical direction, the first distance between the bottom of the first top gate and the top of the first source/drain feature is greater than a sum of the thickness of the first nanostructure and a thickness of the inner spacer layer.

20. The semiconductor structure as claimed in claim 15, further comprising:
a second group of nanostructures;
a second source/drain feature adjoining the second group of nanostructures; and
a second gate stack wrapping around the second group of nanostructures, wherein:
a first number of the nanostructures in the first group is less than a second number of the nanostructures in the second group.
